(19) United States
(12) Patent Application Publication
(10) Pub. No.: US 2015/0003013 A1
(43) Pub. Date: Jan. 1, 2015

(54) ELECTRONIC DEVICE HAVING MAXIMUM HEAT DISSIPATING PROPERTIES

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAI-DONG TANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/078,572

(22) Filed: Nov. 13, 2013

(30) Foreign Application Priority Data
Jun. 27, 2013 (CN) 2013102604302

(51) Int. Cl. H05K 7/20

(52) U.S. Cl. CPC H05K 7/20436; H05K 7/20127
USPC 361/692

(57) ABSTRACT

An electronic device includes a casing with plurality of openings, a printed circuit board (PCB), a heat radiation member, and a conductive member. The PCB with at least one heating element and a plurality of connectors is received in the casing. The heat radiation member is mounted on the PCB and received in the casing. The conductive member is connected with the connectors and the heat radiation member. The connectors correspond to the openings in a one-to-one relationship. Each of the connectors is partly inserted into the corresponding openings. The heat radiation member conducts the heat generated by the heating element to the connectors for dissipating the heat to the outside of the electronic device through the corresponding openings.

### BACKGROUND

1. Technical Field

The present disclosure relates to electronic devices, particular relates to an electronic device with a heat radiating member.

2. Description of Related Art

Electronic devices, such as DVD players, include a casing, a plurality of electronic elements received in the casing. The casing defines a plurality of openings for dispersing heat generated by the electronic elements when the electronic device runs. However, the number of the openings is limited, and the heat dispersing efficiency of the electronic device is limited as a result.

Therefore, there is room for improvement in the art.

### BRIEF DESCRIPTION OF THE FIGURE

The components of the drawings are not necessarily drawn to scale, the emphasis instead being placed upon clearly illustrating the principles of the embodiment of an electronic device. Moreover, in the drawings, like reference numerals designate corresponding parts throughout several views.

FIG. 1 is a schematic view of an electronic device, according to an embodiment.

FIG. 2 is a partially disassembled view of the electronic device of FIG. 1, the electronic device includes a heat radiating member and a conductive member.

FIG. 3 shows another view of the heat radiating member of FIG. 2.

FIG. 4 is an enlarged view of the conductive member of FIG. 2.

FIG. 5 is a cross sectional view of the electronic device of FIG. 1, taken along a line V-V thereof.

### DETAILED DESCRIPTION

Embodiments of the present disclosure will be described in detail with reference to the drawings.

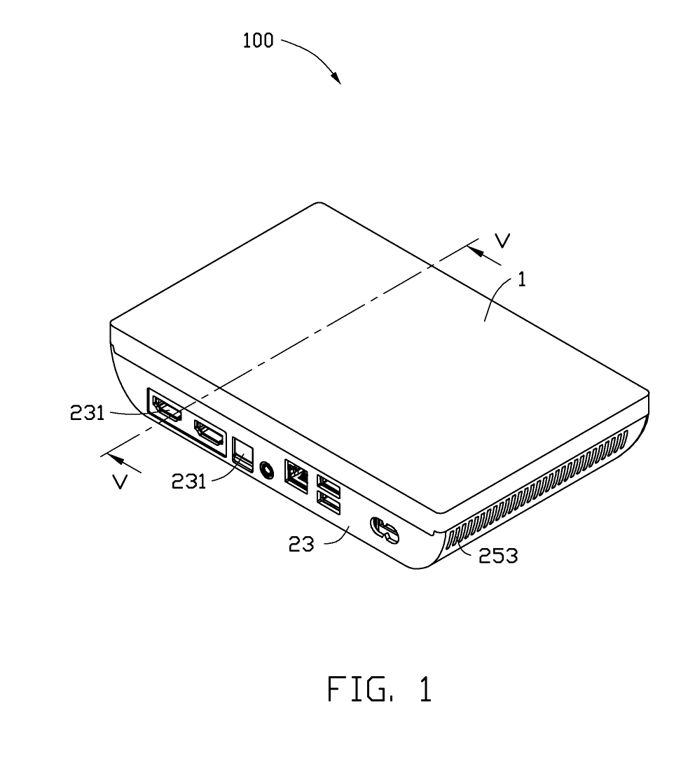

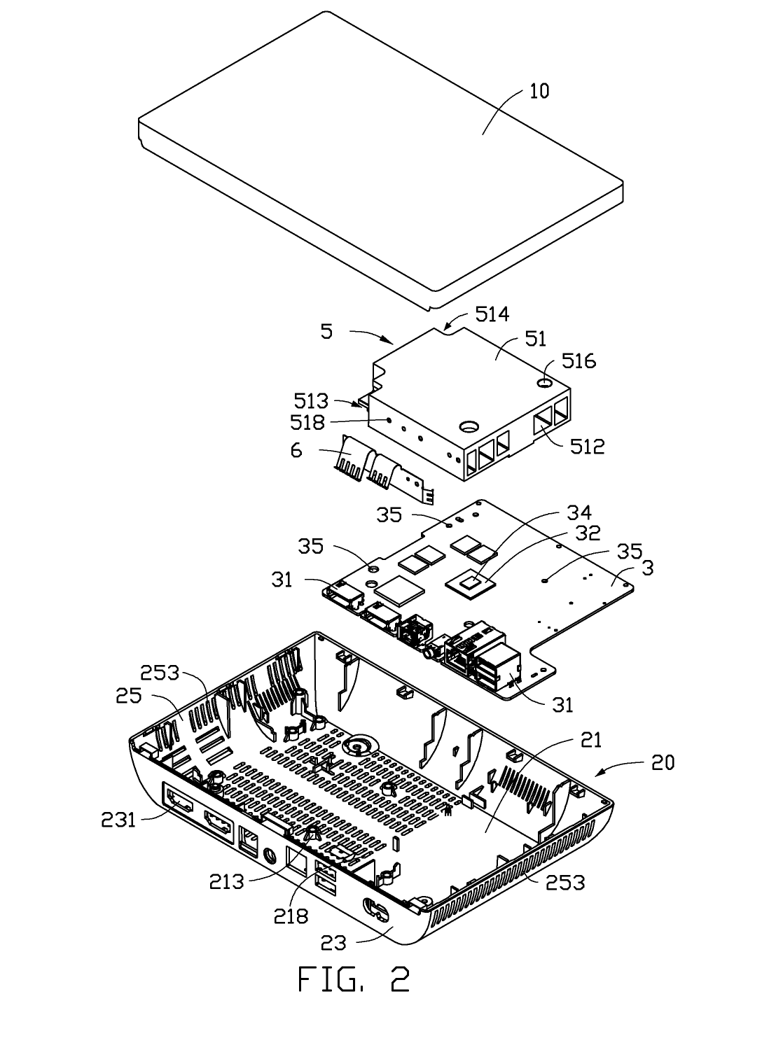

FIGS. 1 and 2 show an electronic device 100 of an embodiment. The electronic device 100 simultaneously disperses heats via a plurality of openings and a plurality of interfaces. In the illustrated embodiment, the electronic device 100 is a set-top box.

The electronic device 100 includes a casing 1, a printed circuit board (PCB) 3, a heat radiation member 5, and a conductive member 6. The PCB 3, the heat radiation member 5, and the conductive member 6 are received in the casing 1.

The casing 1 includes a top cover 10 and a bottom cover 20. The top cover 10 and the bottom cover 20 cooperate with each other to define a closed space for receiving the elements of the electronic device 100. The bottom cover 20 includes a bottom plate 21, a first sidewall 23, and second sidewalls 25. The bottom plate 21 is substantially rectangular. The bottom plate 21 includes four fixing portions 213 and a plurality of first slots 218. The fixing portion 213 is substantially a hollow cylinder. The fixing portion 213 is perpendicularly extended from the bottom plate 21, and an inner sidewall of the fixing portion 213 defines a screw thread. The first slots 218 are arranged in lines which are parallel with each other. The first sidewall 23 and the second sidewalls 25 perpendicularly extend from four adjacent edges of the bottom plate 21. The first sidewall 23 defines a plurality of openings 231 with different sizes. The second sidewall 25 defines a plurality of second slots 253 parallel with each other.

The PCB 3 is sandwiched between the bottom plate 21 and the heat radiation member 5. The PCB 3 includes a plurality of connectors 31 of different types, a heat producing element 32, and a heat conduction portion 34. The connectors 31 correspond to the openings 231 in a one-to-one relationship, and are partly inserted into the corresponding openings 231. The heat producing element 32 is mounted on the PCB 3. The heat conduction portion 34 is arranged on the top surface of the heat element 32 opposite to the PCB 3. The PCB 3 further defines a plurality of holes 35 with two different diameters. The holes 35 correspond to the fixing portions 213 respectively. A region around the holes 35 (not labeled) is conductive. In the embodiment, the connectors 31 can be a universal serial bus (USB) connector, a high definition multimedia interface (HDMI) connector, or a network connector, for example; the heat producing element 32 is a central process unit (CPU).

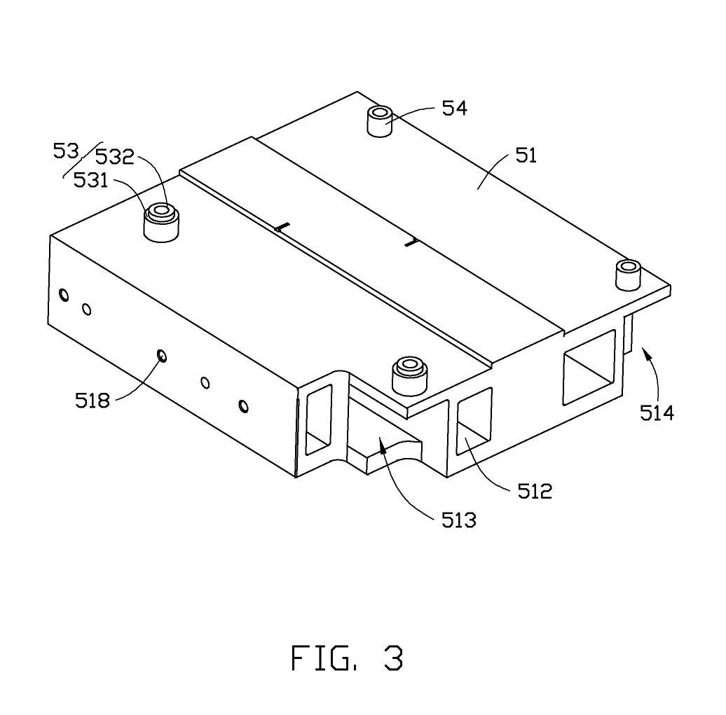

The heat radiation member 5 includes a main body 51, two first supporting portions 53, and two second supporting portions 54. The main body 51 is substantially rectangular. The main body 51 defines a plurality of heat conduction cavities 512 with different sizes, two through holes 516, and a plurality of position holes 518. The heat conduction cavities 512 through the main body 21 are parallel with the first sidewall 23, and facing the second slots 253. The through holes 516 through the main body 51 are arranged in a line perpendicular to the first sidewall 23. The position holes 518 are arranged in a line on the sidewall of the main body 51 facing the first sidewall 23, and an inner surface of the position holes 518 defines a screw thread. The main body 51 further includes a first portion 513 and a second portion 514. The first portion 513 and the second portion 514 are arranged in a line perpendicular to the first sidewall 23, and are concaved from one edge of the main body 21. The first portion 513 is adjacent to the first sidewall 23, and the second portion 514 away from the first sidewall 23. A cross section of the first portion 513 is a substantially two-steps shaped (as shown in FIG. 3). A cross section of the second portion 514 is substantially “L” shaped. Parts of the first portion 513 are through the main body 51. The first portion 513, the second portion 514, and the through holes 516 are used for indicating a position direction while mounting the heat radiation member 5 on the bottom plate 21.

The first supporting portions 53 and the second supporting portions 54 correspond to the holes 35, and communicate with one of the heat conduction cavities 512 respectively. The first supporting portion 53 includes a first post 531 and a second post 532. The first post 531 is sandwiched between the main body and the second post 532, and is coaxial to the second post 532. The second post 532 is substantially a hollow cylinder. The diameter of the second post 532 is equal to the hole 35 which is less than the diameter of the first post 531. The height of the second supporting portion 54 is equal to that of the first supporting portion 53.

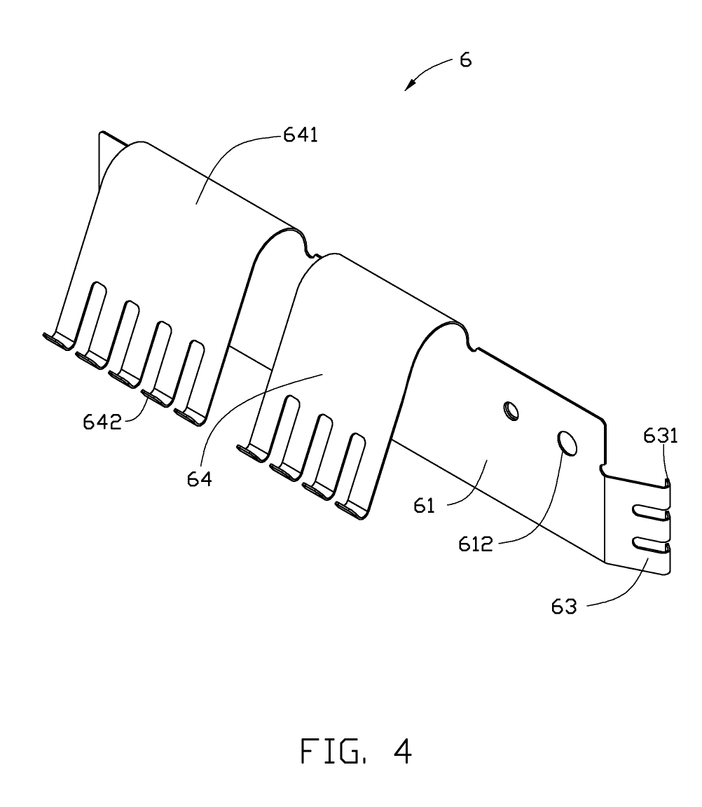

FIG. 4 shows that the conductive member 6 includes a fixing plate 61, a first conductive portion 63, and a plurality of second conductive portions 64. The fixing plate 61 is substantially rectangular. The fixing plate 61 defines a plurality of fixing holes 612 corresponding to the position hole 518. In the embodiment, the conductive member 6 is made of metal.

The first conductive portion 63 and a plurality of second conductive portions 64 extends from two adjacent edges of the fixing plate 61. The first conductive portion 63 is substantially a hook shaped. The first conductive portion 63 extends from the edge of the fixing plate 61 along width direction, and angled with the fixing plate 61. The first conductive portion 63 includes a plurality of first hooks 631 parallel with each other. The bending direction of the first hook 631 is towards the fixing plate 61.

The second conductive portions 64 are parallel with and arranged between the first wall 23 and the main body 51. The second conductive portion 64 is substantially “S” shaped. The second conductive portion 64 includes a bent portion 641 and a plurality of second hooks 642 parallel with each other. The bent portion 641 extends from the edge of the fixing plate 61 along length direction. The bending direction of the bent portion 641 is towards the bottom plate 21. The second hook 642 extends from the edge of the bent portion 641. The bending direction of the second hook 642 is away from fixing plate 61.

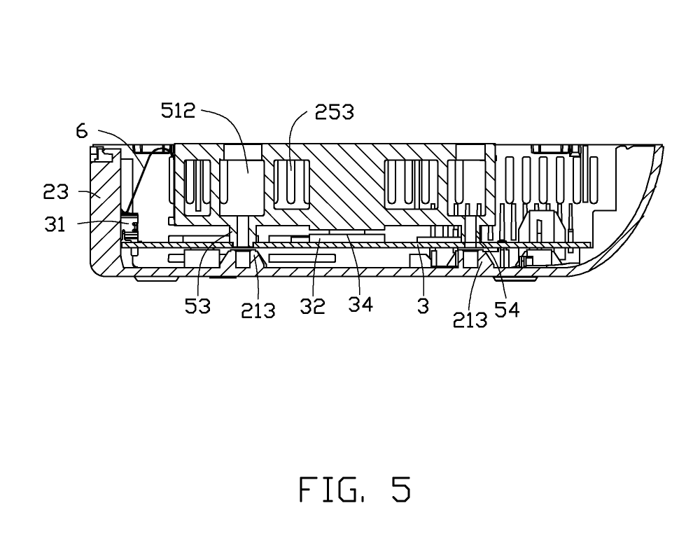

FIG. 5 shows the a cross sectional view of the electronic device 100 taken along a line V-V in assembly, the PCB 3 is arranged on the fixing portions 213 and the connectors 31 are partly inserted into the corresponding openings 231. The heat radiation member 5 is mounted on the PCB 3. The first portion 513 and the second portion 514 face the second slots 253 on the same second sidewall 25. The first portion 513 is adjacent to the first sidewall 23, and the second portion 514 is away from the first sidewall 23. The second post 532 of the first supporting portion 53 is inserted into the corresponding hole 35, and the first post 531 of the first supporting portion 53 resists the PCB 3. The second supporting portions 54 face the corresponding hole 35, and resist the PCB 3. The first supporting portions 53 and the second supporting portion 54 are fixed with the corresponding fixing portion 213. The main body 51 connects with the heat conduction portion 34. Thus, the PCB 3 and the heat radiation member 5 are fixed on the bottom plate 21. The fixing plate 61 is mounted on the side surface of the main body 51 through the position holes 518 and the fixing holes 612. The first conductive portion 63 and the second conductive portion 64 are connected with the corresponding connectors 31 respectively. The heat radiation member 5 disperses the heat generated by the heating element 32 to the outside of the electronic device 100 through the openings 231, the first slot 218, and the second slots 253 respectively. Therefore, the heat radiation effectiveness of the electronic device 100 is improved, and the impact to the electronic device 100 from the static electricity generated by the connector 31 is reduced.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. An electronic device, comprising:
a casing with a plurality of openings;
a printed circuit board (PCB) with at least one heating element and a plurality of connectors received in the casing;
a heat radiation member mounted on the PCB and received in the casing; and
a conductive member connected with the connectors and the heat radiation member;
wherein the connectors correspond to the openings in a one-to-one relationship, each of the connectors is partly inserted into the corresponding openings; the heat radiation member conducts the heat generated by the heating element to the connectors by the conductive member for dissipating the heat through the corresponding openings to the outside of the electronic device.

2. The electronic device of claim 1, wherein the conductive member comprises fixing plate, a first conductive portion, and a plurality of second conductive portions; the first conductive portion and the second conductive portions are extended from two adjacent edges of the fixing plate, and connects with the connectors respectively.

3. The electronic device of claim 2, wherein the first conductive portion is a substantially hook shaped.

4. The electronic device of claim 1, wherein the first conductive portion extends from the edge of the fixing plate along a width direction and angled with the fixing plate.

5. The electronic device of claim 4, wherein the end of the first conductive portion away from the fixing plate comprises a plurality of first hooks; the bending direction of the first hook is towards the fixing plate.

6. The electronic device of claim 2, wherein the second conductive portions parallel with each other, each of the second conductive portion is substantially “S” shaped.

7. The electronic device of claim 6, wherein each of the second conductive portions comprises a bent portion and a plurality of second hooks parallel with each other; the bent portion extends from the edge of the fixing plate along length direction; the bending direction of the bent portion is opposite to the bending direction of the second hook; each of the second hooks extends from the edge of the bent portion.

8. The electronic device of claim 1, wherein the heat radiation member comprises a main body; the casing further defines a plurality of slots; the main body defines a plurality of heat conduction cavities with different sizes; the heat conduction cavities faces the slots respectively for radiating heat.

9. The electronic device of claim 1, wherein the heat radiation member comprises a main body; the main body further comprises a first portion and a second portion for indicating a position direction while mounting the heat radiation member; the first portion and the second portion are arranged in a line perpendicular to the connectors; the first portion and the second portion are different from each other.

10. The electronic device of claim 9, wherein the first portion is concaved from one edge of the main body and adjacent to the connectors.

11. The electronic device of claim 10, wherein parts of the first portion are through the main body.

12. The electronic device of claim 8, wherein the second portion is concaved from one edge of the main body opposite to the first-proof portion.
